(19) United States
(12) Patent Application Publication
(10) Pub. No.: US 2025/0048609 A1
(43) Pub. Date: Feb. 6, 2025

(54) COMPONENT-MOUNTING SYSTEM, COMPONENT MOUNTER, AND COMPONENT-MOUNTING METHOD

(71) Applicant: FUJI CORPORATION, Chiryu (JP)

(72) Inventors: Hiroo MURAOKA, Nagoya-shi (JP); Kazuhiro YASUI, Nagoya-shi (JP); Taesoo PARK, Chiryu-shi (JP); Nobuaki MINOSHIMA, Tougou-cho, Aichi-gun (JP); Makoto YAMAZAKI, Chiryu-shi (JP)

(73) Assignee: FUJI CORPORATION, Chiryu (JP)

(21) Appl. No.: 18/718,986

(22) PCT Filed: Dec. 24, 2021
(86) PCT No.: PCT/JP2021/048355

§ 371 Date: Jun. 12, 2024

(51) Int. Cl. H05K 13/08

(52) U.S. Cl. CPC H05K 13/0815; H05K 13/0812; H05K 13/0882

(57) ABSTRACT

A component-mounting system includes a print inspection machine inspects a solder pattern printed on a board; a component mounter mounts a component on the inspected board; and a board visual inspection machine inspects the board with the mounted component. In a case where a correction value calculated using at least one of an inspection result of the print inspection machine and an inspection result of the board visual inspection machine is equal to or greater than a first set value, a control unit mounts the component at a correction mounting position obtained by correcting a mounting position set in advance using the correction value. On the other hand, in a case where the correction value is less than the first set value, the control unit mounts the component at the mounting position without correcting using the correction value.

### TECHNICAL FIELD

The technology disclosed in the present description relates to a component-mounting system, a component mounter, and a component-mounting method for mounting a component on a board.

### BACKGROUND ART

Multiple production facilities (for example, a solder printing machine, a component mounter, a board inspection machine, a reflow oven, and the like) are installed in a component-mounting line for mounting a component on a board. The boards are subsequently conveyed to the multiple production facilities, and predetermined processing is performed on the board in each production facility, so that the component is mounted on the board. Incidentally, there is a mechanical variation in each production facility, and therefore, a positional deviation may occur for mounting a component.

Therefore, as a conventional technique, a component-mounting system has been developed in which processing of determining the amount of offset correction based on the amount of positional deviation obtained by inspection by a board inspection machine is performed, and a component is mounted at a position corrected by the determined amount of offset correction (for example, Japanese Patent Application Laid-Open No. 2018-56447). In this conventional technique, in a case where there is a positional deviation within a predetermined range, the positional deviation information is automatically fed back to the board inspection machine, and offset correction processing is performed based on this information. However, in a case where the positional deviation is excessive, since there is a possibility that an abnormality has occurred, the positional deviation information is not fed back and the offset correction is not performed. In a case where there is an intermediate positional deviation, the operator determines whether to perform feedback.

### BRIEF SUMMARY

### Technical Problem

However, in the component-mounting system in the conventional technique, even in a case where the positional deviation of a mounted component is extremely small, the offset correction processing of the mounted component is uniformly performed on the component mounter. Therefore, particularly in a case where the number of mounted components is large, there is a problem that the communication time and the communication volume of information transmitted and received between the production facilities become enormous, and a tact delay is caused. In addition, since it is necessary to perform an enormous amount of information communication each time, the load of processing performed by the control device constituting the component-mounting system is large.

Therefore, the present description provides a technique capable of reducing the load on a control device constituting a component-mounting system.

### Solution to Problem

The present description discloses a component-mounting system. A component-mounting system includes a print inspection machine that inspects a solder pattern printed on a board, a component mounter that mounts a component on the board inspected by the print inspection machine, and a board visual inspection machine that inspects the board on which the component is mounted by the component mounter. The component mounter includes a mounting unit that mounts the component on the board, and a control unit that controls the mounting unit. In a case where a correction value calculated using at least one of an inspection result of the print inspection machine and an inspection result of the board visual inspection machine is equal to or greater than a first set value, the control unit mounts the component at a correction mounting position obtained by correcting a mounting position set in advance using the correction value. On the other hand, in a case where the correction value is less than the first set value, the control unit mounts the component at the mounting position without correcting using the correction value.

In the above-described configuration, in a case where the correction value is equal to or greater than the first set value, the control unit mounts the component at the correction mounting position. However, in a case where the correction value is less than the first set value, the control unit mounts the component at the mounting position without correcting. That is, the correction is not intentionally performed on the positional deviation which is not necessary to be corrected and is within the allowable range. Therefore, the frequency of the offset correction processing is reduced, and the communication time and the communication volume of information necessary for the processing are reduced, so that the tact delay can be avoided. In addition, it is possible to reduce a load of processing performed by the control unit constituting the component-mounting system.

In addition, the present description discloses a component mounter. The component mounter includes a mounting unit that mounts a component on a board, a board conveyance device, and a control unit that controls the mounting unit. The board conveyance device carries a board conveyed from a print inspection machine that inspects a solder pattern printed on the board into a component mounting position. At the same time, the board conveyance device carries out the board on which the component is mounted at the component mounting position by the mounting unit to the board visual inspection machine. In a case where a correction value calculated using at least one of an inspection result of the print inspection machine and an inspection result of the board visual inspection machine is equal to or greater than a first set value, the control unit mounts the component at a correction mounting position obtained by correcting a mounting position set in advance using the correction value. On the other hand, in a case where the correction value is less than the set value, the control unit mounts the component at the mounting position without correcting using the correction value.

According to such a configuration, similar to the above, the correction is not intentionally performed on the positional deviation which is not necessary to be corrected and is within the allowable range. Therefore, the same effects as those of the component-mounting system described above can be achieved.

In addition, the present description also discloses a component-mounting method. The component-mounting method includes a print inspection step of inspecting a solder pattern printed on a board, a component-mounting step of mounting a component on the board inspected in the print inspection step, and a board visual inspection step of inspecting the board on which the component is mounted in the component-mounting step. In the component-mounting step, in a case where a correction value calculated using at least one of an inspection result of the print inspection step and an inspection result of the board visual inspection step is equal to or greater than a first set value, the component is mounted at a correction mounting position obtained by correcting a mounting position set in advance using the correction value. In addition, in the component-mounting step, in a case where the correction value is less than the first set value, the component is mounted at the mounting position without correcting using the correction value.

According to such a configuration, similar to the above, the correction is not intentionally performed on the positional deviation which is not necessary to be corrected and is within the allowable range. Therefore, the same effects as those of the component-mounting system described above can be achieved.

### BRIEF DESCRIPTION OF DRAWINGS

FIG. 1 is a schematic diagram of a component-mounting system of a first example.

FIG. 2 is a diagram illustrating a relationship between the amount of positional deviation for each component and a first correction value and a set value (a first set value and a second set value).

FIG. 3 is a schematic diagram of a graph displayed on a graph output device.

FIG. 4 is a schematic diagram of a graph displayed on the graph output device.

FIG. 5 is a flowchart illustrating processing in a print inspection machine.

FIG. 6 is a flowchart illustrating processing in a component mounter.

FIG. 7 is a schematic diagram of a component-mounting system of a second example.

FIG. 8 is a flowchart illustrating processing in a board visual inspection machine of the component-mounting system of the second example.

### DESCRIPTION OF EMBODIMENTS

Main features of an example, which will be described below, will be listed. Technical elements described below are mutually independent technical elements that exhibit technical usefulness by themselves or by various combinations, and are not limited to the combinations described in the claims as filed.

(Feature 1) The control unit may stop mounting the component on the board in a case where the correction value is equal to or greater than a second set value greater than the first set value.

Since there is a high possibility that the correction value equal to or greater than the second set value is an abnormal value, there is a possibility that some abnormality occurs rather than performing the correction by the offset correction processing. According to such a configuration, the cause of the occurrence of the abnormal value can be determined at that time, and countermeasures can be taken as necessary, which consequently contributes to improving productivity.

(Feature 2) The print inspection machine or the board visual inspection machine may include a correction value calculation section that calculates the correction value using the inspection result. In addition, the print inspection machine or the board visual inspection machine may include a communication section that does not transmit the correction value calculated by the correction value calculation section to the component mounter in a case where the correction value is less than the first set value, while transmitting the correction value to the component mounter in a case where the calculated correction value is equal to or greater than the first set value.

According to such a configuration, the communication section transmits the correction value to the component mounter only in a case where the correction value calculated by the correction value calculation section is equal to or greater than the first set value. Therefore, it is possible to reduce the time required for information communication of the correction value for mounting the component compared to the conventional technique.

(Feature 3) The board may include at least one land and a lead component mounted on the land. The component-mounting system may further include a graph output device that outputs a graph indicating a time-series change in the amount of deviation of the lead component with respect to the land. The amount of deviation of the lead component with respect to the land may be calculated based on the inspection result of the board visual inspection machine.

According to such a configuration, the graph output device displays the graph indicating the time-series change in the amount of deviation of the lead component with respect to the land, so that it is possible to obtain in more detail through visual observation how effective the offset correction processing is and how much the offset correction processing contributes. In addition, the cause, transition, and the like of the positional deviation can be visually obtained.

(Feature 4) The print inspection machine may include a first correction value calculation section that calculates a first correction value using an inspection result of a solder pattern printed on the board. In addition, the print inspection machine may include a first communication section that does not transmit the first correction value calculated by the first correction value calculation section to the component mounter and the board visual inspection machine in a case where the first correction value is less than a first set value, while transmitting the first correction value to the component mounter and the board visual inspection machine in a case where the calculated first correction value is equal to or greater than the first set value. The board visual inspection machine may include a second correction value calculation section that calculates a second correction value using a visual inspection result of the component mounted on the board and the first correction value transmitted from the first communication section. In addition, the board visual inspection machine may include a second communication section that does not transmit the second correction value calculated by the second correction value calculation section to the component mounter in a case where the second correction value is less than a third set value, while transmitting the second correction value to the component mounter in a case where the calculated second correction value is equal to or greater than the third set value. The control unit of the component mounter may mount the component at the correction mounting position calculated using the first correction value and the second correction value in a case where the first correction value and the second correction value are received.

According to such a configuration, only in a case where the first correction value calculated using the inspection result of the solder pattern is equal to or greater than the first set value, the first correction value is transmitted to the component mounter and the board visual inspection machine by the first communication section of the print inspection machine. In addition, only in a case where the second correction value calculated using the visual inspection result of the component and the first correction value is equal to or greater than the second set value, the second correction value is transmitted to the component mounter by the second communication section of the board visual inspection machine. In a case where the first correction value and the second correction value are received, the control unit of the component mounter mounts the component at the correction mounting position calculated using the first correction value and the second correction value. In addition, in a case where one of the first correction value and the second correction value is received, the control unit of the component mounter mounts the component at the correction mounting position calculated using the received correction value. On the other hand, in a case where either the first correction value or the second correction value is not received, the control unit of the component mounter mounts the component at the mounting position without correcting.

### First Example

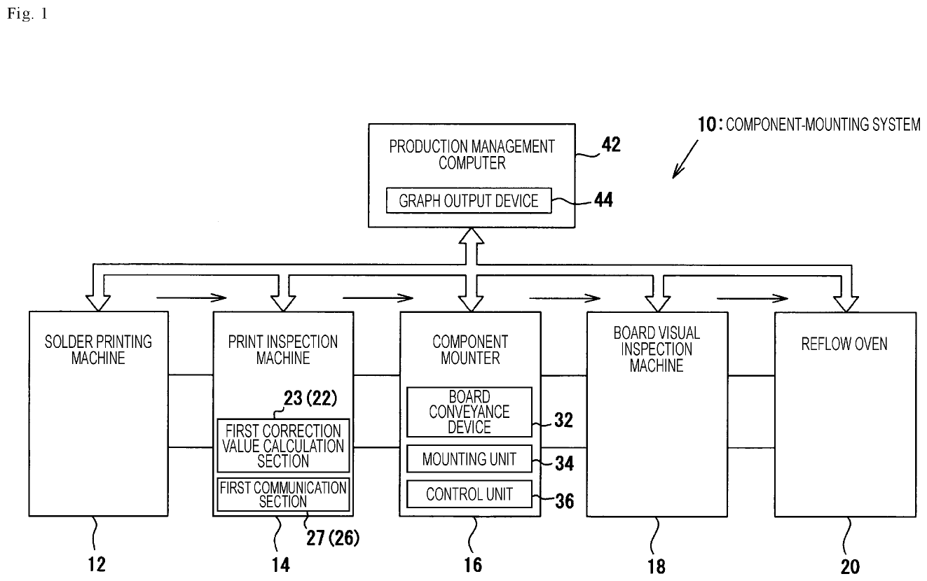

Hereinafter, component-mounting system 10 of Example 1 will be described with reference to FIGS. 1 to 6. As illustrated in FIG. 1, component-mounting system 10 includes multiple production facilities installed in a component-mounting line, and production management computer 42 that manages multiple production facilities.

The production facility constitutes the component-mounting line for mounting a component on a board. The component-mounting line mounts the component on the board to be loaded and manufactures the board on which the component is mounted. The board includes at least one land and a lead component mounted on the land. The board may include at least one pad and a chip component mounted on the pad. Hereinafter, a board after the component is mounted may be referred to as a circuit board, and a board before the component is mounted or during the component is mounted may be simply referred to as a board.

The component-mounting line includes a board loader (not illustrated), solder printing machine 12, print inspection machine (SPI) 14, component mounter 16, board visual inspection machine (AOI) 18, reflow oven 20, and a board unloader (not illustrated), as multiple production facilities. Since a well-known machine used in a well-known component-mounting line can be used, these production facilities will be briefly described below.

The board loader loads the board into the component-mounting line. The board loader accommodates multiple boards and carries out the accommodated boards one by one to solder printing machine 12. Solder printing machine 12 prints a pattern of the solder on the board carried from the board loader. The board on which the solder pattern is printed is conveyed from solder printing machine 12 to print inspection machine 14. Print inspection machine 14 inspects whether a solder pattern printed on the board is normal. In a case where an abnormality occurs in the printed solder pattern (for example, in a case where a printing failure occurs due to clogging of a mask), the board is discarded. On the other hand, in a case where the printed solder pattern is normal, the board is carried out from print inspection machine 14 to component mounter 16. Component mounter 16 includes board conveyance device 40. Board conveyance device 40 carries the board conveyed from the print inspection machine into the component mounting position. Component mounter 16 includes mounting unit 34 that mounts multiple predetermined components on the board carried into the component mounting position. Specifically, mounting unit 34 includes multiple component feeders detachably attached, and mounts the components supplied from the component feeders on the board. The board on which the component is mounted by component mounter 16 is carried out to board visual inspection machine 18 by board conveyance device 40. Board visual inspection machine 18 inspects whether the component is normally mounted on the board. In a case where the component is not normally mounted on the board (for example, in a case where the component is mounted on a different place), the board is discarded. On the other hand, in a case where the component is normally mounted on the board, the board is carried out from board visual inspection machine 18 to reflow oven 20. Reflow oven 20 heats the carried board to melt the solder, thereby soldering the component to the board. The board carried out from reflow oven 20 is carried out to a board unloader. The board unloader carries out the circuit board on which the component is mounted from the component-mounting line.

Each production facility includes a communication circuit. The communication circuit is communicably connected to production management computer 42. Each communication circuit outputs state information indicating the state of the production facility equipped with the communication circuit to production management computer 42. For example, the board loader outputs the number of boards to be accommodated to production management computer 42. Accordingly, production management computer 42 can determine whether a board needs to be replenished to the board loader. In addition, for example, component mounter 16 outputs the number of used components to production management computer 42 for each type of component. Accordingly, production management computer 42 can determine whether components need to be replenished to component mounter 16.

Production management computer 42 includes CPU and memory, and controls the production of the circuit board by controlling the operation of each production facility. For example, production management computer 42 transmits the print pattern of the solder to print inspection machine 14. Print inspection machine 14 inspects the board by the received print pattern. In addition, for example, production management computer 42 transmits a mounting program (mounting job) that defines the type, mounting order, and mounting position of the component to be mounted on component mounter 16. Component mounter 16 mounts the component on the board based on the received mounting program.

In addition, production management computer 42 determines the operation state of each production facility based on the state information output from each production facility. For example, when the component feeder needs to be exchanged, component mounter 16 outputs information to that effect to production management computer 42. Production management computer 42 can determine that the component feeder needs to be exchanged in component mounter 16 based on the information output from component mounter 16.

Component-mounting system 10 of the present example includes a configuration for mounting the component at an offset-corrected position in a case where a positional deviation occurs in the board. The positional deviation occurring in the board includes two types of positional deviation occurring in the board carried out from solder printing machine 12 and positional deviation occurring in the board carried out from component mounter 16. The positional deviation occurring in the board carried out from solder printing machine 12 refers to the positional deviation of the solder pattern printed on the board. Examples of the positional deviation include the positional deviation of the solder pattern with respect to the land on the board. In addition, examples of the positional deviation occurring in the board carried out from component mounter 16 include the positional deviation of the lead component after mounting with respect to the land on the board.

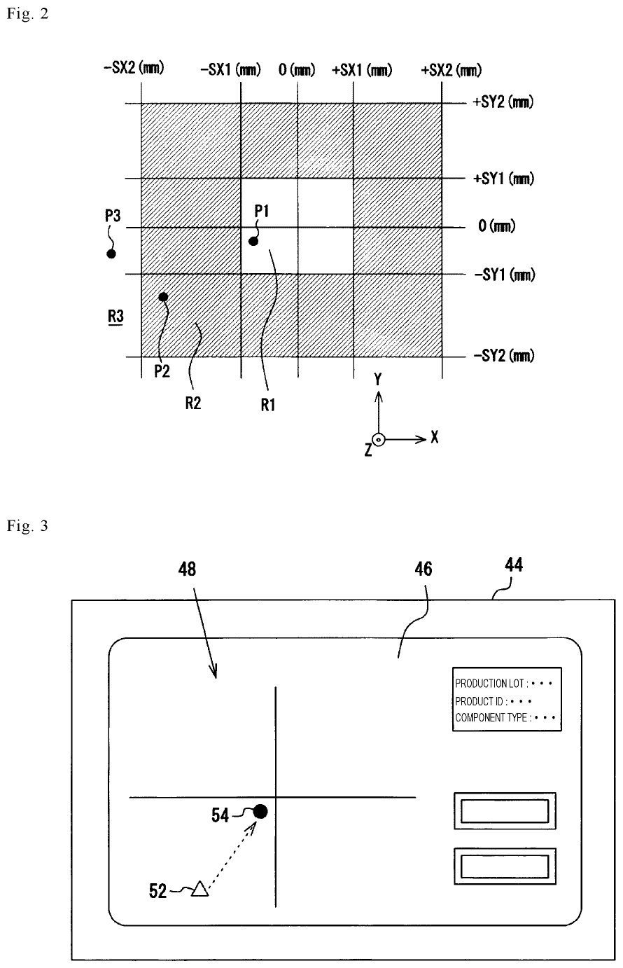

Print inspection machine 14 includes correction value calculation section 22 (first correction value calculation section 23) that calculates a correction value using the inspection results. First correction value calculation section 23 calculates a first correction value for performing the offset correction for eliminating the positional deviation using the inspection result of the solder pattern printed on the board. Print inspection machine 14 includes a computer including CPU, memory, and the like, and the CPU functions as first correction value calculation section 23. FIG. 2 is a diagram illustrating a relationship between a first correction value and a set value (a first set value and a second set value). In this drawing, the vertical direction is the X axis, and the horizontal direction is the Y axis. In this drawing, a matrix created by drawing multiple straight lines vertically and horizontally is drawn. The center of the matrix is the point where the correction value obtained from the inspection result by print inspection machine 14 is zero in both the X direction and the Y direction. That is, this point indicates a mounting position set in advance. In the drawing, “−SX1” indicates a negative first set value in the X direction, and “+SX1” indicates a positive first set value in the X direction. “−SY1” indicates a negative first set value in the Y direction, and “+SY1” indicates a positive first set value in the Y direction. In addition, “−SX2” indicates a negative second set value in the X direction, and “+SX2” indicates a positive second set value in the X direction. “−SY2” indicates a negative second set value in the Y direction, and “+SY2” indicates a positive second set value in the Y direction. Points P1, P2, and P3 in the drawing indicate the first correction values calculated for each component.

For example, in a case where the first correction value calculated by first correction value calculation section 23 is less than the first set value, that is, in a case where the first correction value is within the range of ±SX1 and the range of ±SY1, point P1 indicating the first correction value is plotted in the region indicated by R1 in FIG. 2. In a case where the first correction value calculated by first correction value calculation section 23 is equal to or greater than the second set value, that is, in a case where the first correction value is out of the range of ±SX2 or out of the range of ±SY2, point P3 indicating the first correction value is plotted in the region indicated by R3 in FIG. 2. In a case where the first correction value calculated by first correction value calculation section 23 is equal to or greater than the first set value and less than the second set value, that is, in a case where the first correction value is in the range of −SX2 to −SX1, the range of +SX1 to +SX2, the range of −SY2 to −SY1, or the range of +SY1 to +SY2, point P2 indicating the first correction value is plotted in the hatched region indicated by R2 in FIG. 2. Since hatched region R2 is not within an allowable range, hatched region R2 indicates a positional deviation that requires the offset correction. The range of hatched region R2 is set in advance for each component, each component type, each lot, each device type, or each module (for example, each mounting head type), for example. On the other hand, region R1 does not need to be offset corrected, and indicates a positional deviation within an allowable range (within a variation allowable range).

In the present example, since multiple components are mounted on the board by component mounter 16, the above-described first correction value is calculated for each component mounted on the board. That is, a first correction value is calculated by inspecting (measuring) the positional deviation of the solder pattern and calculating the difference between the inspection result (measurement result) and the mounting position set in advance for each of the multiple components mounted by component mounter 16. By individually calculating the first correction value for each component, each component can be mounted on the board with high accuracy. Alternatively, one first correction value may be calculated for multiple components mounted by component mounter 16. For example, in a case where the cause of the positional deviation caused by solder printing machine 12 is the positional deviation between the board and the mask, the solder pattern is deviated by the same amount in the same direction in each of the mounted components. Therefore, one first correction value may be calculated, and the calculated one first correction value may be used for all the components. In this case, for example, one first correction value may be calculated by inspecting (measuring) the positional deviation of the solder pattern, calculating a difference between the inspection result (measurement result) and the mounting position set in advance, and averaging the calculated values for some of the multiple components mounted by component mounter 16.

Print inspection machine 14 includes communication section 26 (first communication section 27). The CPU that constitutes print inspection machine 14 functions as first communication section 27. First communication section 27 transmits the first correction value calculated by first correction value calculation section 23 to the outside via the communication circuit in a predetermined case. That is, in a case where the first correction value is equal to or greater than the first set value, first communication section 27 transmits the first correction value to production management computer 42. On the other hand, in a case where the first correction value is less than the first set value, first communication section 27 does not transmit the first correction value to production management computer 42. Furthermore, in a case where the first correction value is equal to or greater than the second set value, first communication section 27 transmits a stop instruction signal for stopping component mounter 16 to production management computer 42 instead of transmitting the first correction value to production management computer 42.

Production management computer 42 receives the first correction value transmitted from print inspection machine 14, and creates statistical information on the first correction value for each component based on the received first correction value. In addition, production management computer 42 transmits the received first correction value as the first correction value instruction signal to component mounter 16. Furthermore, in a case where the first correction value is equal to or greater than the second set value, production management computer 42 transmits the stop instruction signal received from print inspection machine 14 to component mounter 16.

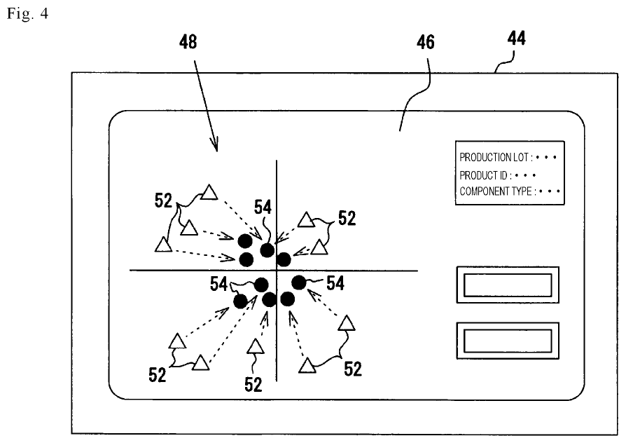

As illustrated in FIGS. 3 and 4, production management computer 42 includes graph output device 44 that outputs predetermined graph 48. For example, graph output device 44 may be a display device such as a liquid crystal display that has display screen 46 displaying graph 48. Graph 48 indicates, for example, a time-series change in the amount of deviation of the lead component with respect to the land. The amount of deviation of the lead component with respect to the land is calculated based on the inspection result of board visual inspection machine 18. For example, in the graph of FIG. 3, point 52 represented by a white triangle (Δ), and point 54 represented by a black circle (⋅) are illustrated. Point 52 indicates the amount of virtual positional deviation when the correction processing is not performed on the specific component (or the amount of positional deviation (statistical value) when the specific component is mounted without the correction processing). On the other hand, point 54 indicates the amount of positional deviation after the correction processing is performed on the specific component. Since point 52 indicated by ⋅ is located closer to the center of the graph than point 54 indicated by Δ, it can be seen that the amount of positional deviation becomes smaller when the correction processing is performed. In the graph of FIG. 4, multiple points 52 and multiple points 54 are illustrated. That is, in this graph, the amount of positional deviation for each sequence after multiple components are mounted on the board is illustrated.

Component mounter 16 includes control unit 36 that controls mounting unit 34. Control unit 36 includes a computer including CPU and memory. Control unit 36 receives the first correction value instruction signal transmitted from production management computer 42 via the communication circuit. In a case where the first correction value calculated using the inspection results of print inspection machine 14 is equal to or greater than the first set value, control unit 36 mounts the component at a correction mounting position obtained by correcting a mounting position set in advance using the first correction value. Specifically, in a case where the first correction value instruction signal is input from production management computer 42, control unit 36 drives and causes mounting unit 34 to mount the component at the correction mounting position. On the other hand, in a case where the first correction value is less than the first set value, control unit 36 mounts the component at the mounting position without correcting using the first correction value. Specifically, in a case where neither the first correction value instruction signal nor the stop instruction signal is input from production management computer 42, control unit 36 drives and causes mounting unit 34 to mount the component at the mounting position without correcting using the first correction value. In addition, in a case where the first correction value is equal to or greater than the second set value which is greater than the first set value, control unit 36 stops mounting the component on the board. Specifically, control unit 36 does not drive and control mounting unit 34 in a case where the stop instruction signal is input from production management computer 42.

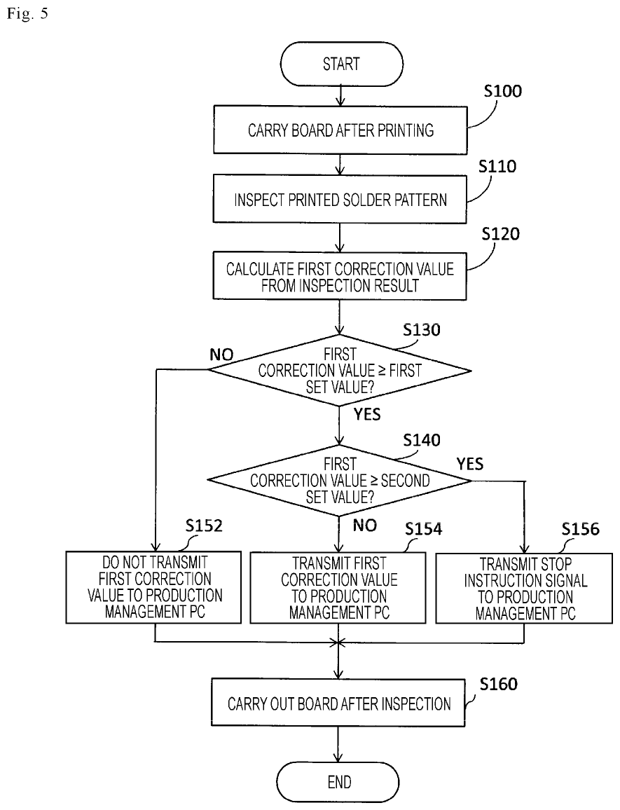

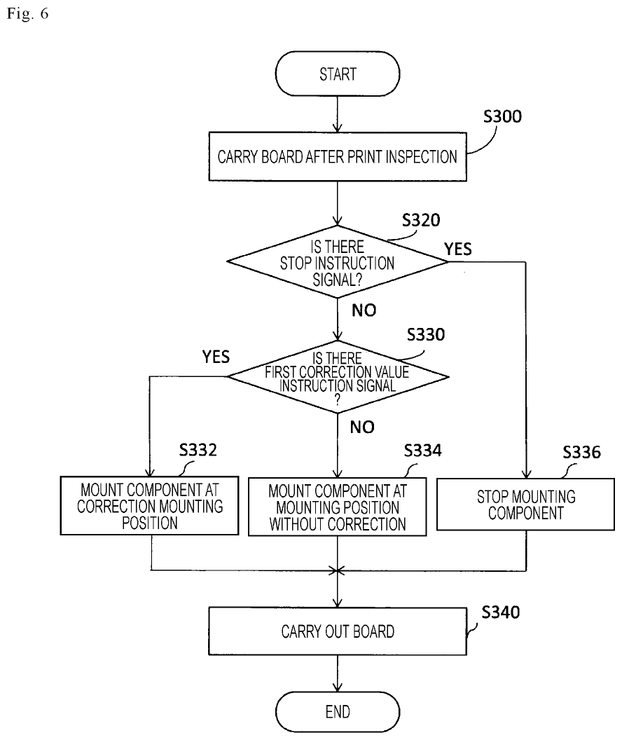

Next, a procedure of the component-mounting method performed by component-mounting system 10 described above will be described with reference to flowcharts of FIGS. 5 and 6.

First, the processing performed by print inspection machine 14 will be described. First, the board after solder pattern printing is conveyed from solder printing machine 12 to print inspection machine 14, and the board is carried into the board inspection position (step S100). Next, print inspection machine 14 inspects whether the solder pattern printed on the board is normal (step S110), and a first correction value is calculated from the inspection result (step S120). Next, the process proceeds to step S130 to compare and determine the calculated first correction value with the first set value. In a case where it is determined that the first correction value is equal to or greater than the first set value (step S130: Y), the process proceeds to next step S140 to compare and determine the first correction value with the second set value. In a case where it is determined that the first correction value is less than the first set value (step S130: N), the first correction value is not transmitted to production management computer 42 (step S152). On the other hand, as a result of the comparison determination between the first correction value and the second set value, in a case where it is determined that the first correction value is less than the second set value (step S140: N), the first correction value is transmitted to production management computer 42 (step S154). In addition, in a case where it is determined that the first correction value is equal to or greater than the second set value (step S140: Y), a stop instruction signal is transmitted to production management computer 42 (step S156). The steps from S120 to S156 are performed for each of the multiple components mounted on one board. After the above steps are performed for all the components, the inspected board is carried out from print inspection machine 14 (step S160).

Next, processing performed in component mounter 16 will be described. First, the printed and inspected board conveyed from print inspection machine 14 to component mounter 16 is carried into the component mounting position (step S300), and the process proceeds to next step S320. In step S320, it is determined whether a stop instruction signal is input. In a case where the stop instruction signal is input (step S320: Y), it is stopped to mount the component (step S336). In a case where the stop instruction signal is not input (step S320: N), the process proceeds to step S330 and it is determined whether the first correction value instruction signal is input. In a case where the first correction value instruction signal is input (step S330: Y), the component is mounted at the correction mounting position (step S332). In a case where the first correction value instruction signal is not input (step S330: N), the component is mounted at the mounting position without correction (step S334). The steps from S310 to S336 are performed for each component on one board. After the above steps are performed for all the components, the board is carried out (step S340).

As described above, in component-mounting system 10 of the present example, in a case where the correction value calculated using the inspection result of print inspection machine 14 is less than the first set value, the component is mounted at the mounting position without correcting using the correction value. That is, the correction is not intentionally performed on the positional deviation which is not necessary to be corrected and is within the allowable range. Therefore, the frequency of the offset correction processing is reduced, and the communication time and the communication volume of information necessary for the processing are reduced, so that the tact delay can be avoided. Therefore, it can contribute to improving productivity. In addition, the load of the processing performed by control unit 36 constituting component-mounting system 10 can be reduced. As a result, it is possible to reduce the introduction cost of the system.

In addition, in component-mounting system 10 of the present example described above, in a case where the first correction value is equal to or greater than the second set value which is greater than the first set value, control unit 36 stops mounting the component on the board. In a case where the first correction value is equal to or greater than the second set value, there is a high possibility that an abnormality has occurred in solder printing machine 12. By stopping mounting the component on the board, the cause of the occurrence of the abnormal value can be determined at that time, and countermeasures can be taken as necessary. Accordingly, it can consequently contribute to improving productivity. In addition, when statistical information on the first correction value for each component is created, since the first correction value equal to or greater than the second set value, which is an abnormal value, is consequently excluded, the accuracy of the first correction value is maintained at a high level.

In addition, in component-mounting system 10 of the present example described above, in a case where the calculated first correction value is less than the first set value, print inspection machine 14 does not transmit the first correction value to component mounter 16 via production management computer 42. Therefore, it is possible to reduce the time required for information communication of the first correction value for mounting the component compared to the conventional technique.

In addition, in component-mounting system 10 of the present example described above, production management computer 42 outputs a graph indicating the time-series change in the amount of positional deviation (for example, graph 48 indicating the time-series change in the amount of deviation of the lead component with respect to the land). By outputting the graph, it is possible to obtain in more detail through visual observation how effective the offset correction processing is and how much the offset correction processing contributes. In addition, the cause, transition, and the like of the positional deviation can be visually obtained.

### Second Example

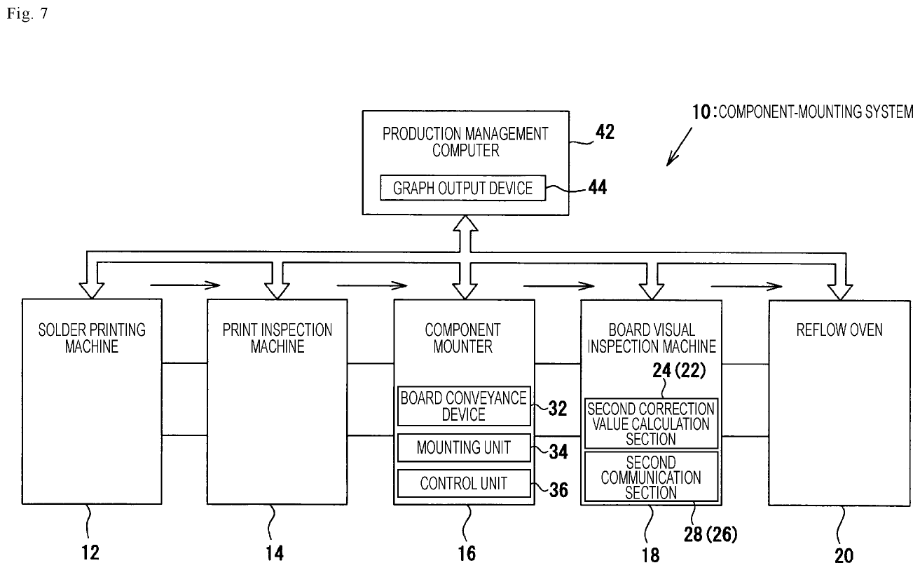

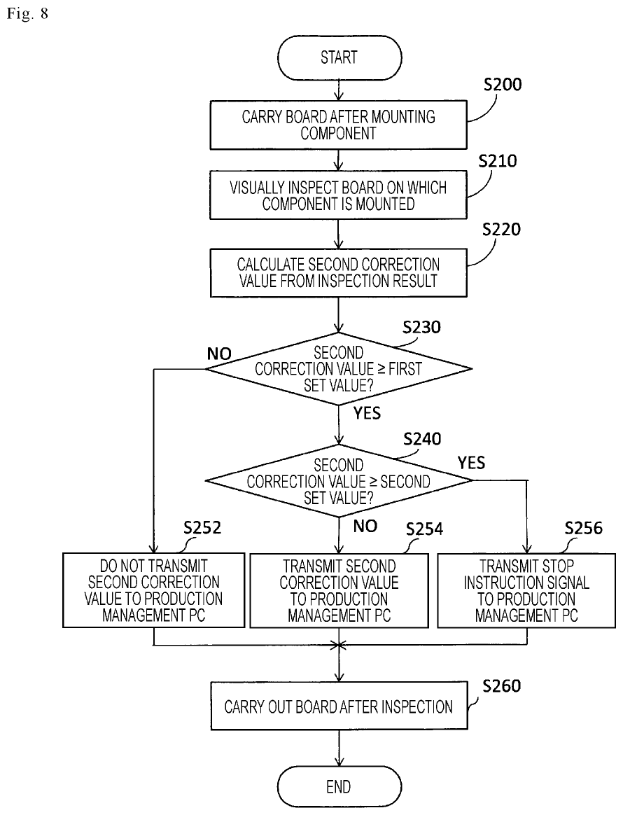

Hereinafter, component-mounting system 10 of Example 2 will be described with reference to FIGS. 7 and 8. In the present example, a configuration different from that of Example 1 will be mainly described. Components that are common to that of Example 1 will be given common member numbers, and detailed descriptions thereof will be omitted. In Example 1 described above, print inspection machine 14 includes correction value calculation section 22 that calculates a correction value using the inspection result performed by itself. On the other hand, in the present example illustrated in FIG. 7, board visual inspection machine 18 includes correction value calculation section 22 that calculates a correction value using the inspection result performed by itself. That is, board visual inspection machine 18 includes correction value calculation section 22 (second correction value calculation section 24) that calculates a second correction value using the result of the board visual inspection. Second correction value calculation section 24 calculates a second correction value for performing offset correction for eliminating the positional deviation using the result of the board visual inspection. Board visual inspection machine 18 includes a computer including CPU, memory, and the like, and the CPU functions as second correction value calculation section 24.

Board visual inspection machine 18 includes communication section 26 (second communication section 28). The CPU constituting board visual inspection machine 18 functions as second communication section 28. Second communication section 28 transmits the second correction value calculated by second correction value calculation section 24 to the outside via the communication circuit in a predetermined case. That is, in a case where the second correction value is equal to or greater than the first set value, second communication section 28 transmits the first correction value to production management computer 42. On the other hand, in a case where the second correction value is less than the first set value, second communication section 28 does not transmit the first correction value to production management computer 42. Furthermore, in a case where the second correction value is equal to or greater than the second set value, second communication section 28 transmits a stop instruction signal for stopping component mounter 16 to production management computer 42 instead of transmitting the second correction value to production management computer 42.

Next, a procedure of the component-mounting method performed by component-mounting system 10 will be described with reference to a flowchart of FIG. 8.

First, the processing performed by board visual inspection machine 18 will be described. First, the board after the component is mounted is conveyed from component mounter 16 to board visual inspection machine 18, and the board is carried into the board inspection position (step S200). Next, the visual inspection of the board on which the component is mounted is performed (step S210), and a second correction value is calculated from the inspection result (step S220). Specifically, the amount of positional deviation between the mounting position where the component is actually mounted and the mounting position set in advance for the component is calculated for the component mounted on the board, and a second correction value is calculated based on the calculated amount of positional deviation. Next, the process proceeds to step S230 to compare and determine the calculated second correction value with the first set value. In a case where it is determined that the second correction value is equal to or greater than the first set value (step S230: Y), the process proceeds to next step S240 to compare and determine the second correction value with the second set value. In a case where it is determined that the second correction value is less than the first set value (step S230: N), the second correction value is not transmitted to production management computer 42 (step S252). On the other hand, as a result of the comparison determination between the second correction value and the second set value, in a case where it is determined that the second correction value is less than the second set value (step S240: N), the second correction value is transmitted to production management computer 42 (step S254). In addition, in a case where it is determined that the second correction value is equal to or greater than the second set value (step S240: Y), the stop instruction signal is transmitted to production management computer 42 (step S256). The steps from S220 to S256 are performed for each mounted component on one board. After the above steps are performed for all the mounted components, the inspected board is carried out from board visual inspection machine 18 (step S260). Production management computer 42 transmits a value obtained by statistical processing (for example, averaging) the second correction value of the component transmitted for each board to component mounter 16 as the second correction value. By using the statistically processed second correction value, the mounting position is corrected based on the tendency of the amount of positional deviation generated in component-mounting system 10.

In component mounter 16, offset correction is performed through basically the same processing as the flowchart illustrated in FIG. 6. That is, after the board after printing inspection is carried (step S300), it is determined whether the stop instruction signal is input. In a case where the stop instruction signal is input (step S320: Y), it is stopped to mount the component (step S336). In a case where the stop instruction signal is not input (step S320: N) and the first correction value instruction signal is input (step S330: Y), the component is mounted at the correction mounting position (step S332). In a case where the stop instruction signal is not input (step S320: N) and the first correction value instruction signal is not input (step S330: N), the component is mounted at the mounting position without correction (step S334). The steps from S310 to S336 are performed for each component on one board. After the above steps are performed for all the components, the board is carried out (step S340).

In component-mounting system 10 of the present example described above, board visual inspection machine 18 transmits the second correction value to component mounter 16 via production management computer 42 only in a case where the calculated second correction value is equal to or greater than the first set value and less than the second set value (that is, only in a case where the calculated second correction value belongs to the range of hatched region R2 in FIG. 2). Therefore, it is possible to reduce the time required for information communication of the second correction value for mounting the component compared to the conventional technique.

### Third Example

Hereinafter, component-mounting system 10 of Example 3 will be described. In the present example, configurations different from those of Examples 1 and 2 will be mainly described. Components that are common to those of Examples 1 and 2 will be given common member numbers, and detailed descriptions thereof will be omitted. In component-mounting system 10 of the present example, print inspection machine 14 and board visual inspection machine 18 each calculate a correction value. That is, print inspection machine 14 includes first correction value calculation section 23 that calculates a first correction value, and first communication section 27 that outputs the first correction value calculated by first correction value calculation section 23 to the outside in a predetermined case. Specifically, in a case where the first correction value is equal to or greater than the first set value, first communication section 27 transmits the first correction value to component mounter 16 and board visual inspection machine 18 via production management computer 42. On the other hand, in a case where the first correction value is less than the first set value, first communication section 27 does not transmit the first correction value to component mounter 16 and board visual inspection machine 18. Furthermore, in a case where the first correction value is equal to or greater than the second set value, first communication section 27 transmits a stop instruction signal for stopping component mounter 16 to component mounter 16 via production management computer 42 instead of transmitting the first correction value.

Board visual inspection machine 18 includes second correction value calculation section 24 that calculates a second correction value, and second communication section 28 that outputs the second correction value calculated by second correction value calculation section 24 to the outside in a predetermined case. Here, in a case where the first correction value calculated by print inspection machine 14 is equal to or greater than the first set value and less than the second set value, the amount of positional deviation measured by board visual inspection machine 18 includes a result corrected by the first correction value output from print inspection machine 14. Therefore, when calculating a second correction value, the amount of positional deviation between the correction mounting position obtained by correcting the mounting position set in advance with the first correction value and the inspection result (that is, the actually mounted position) of board visual inspection machine 18 is calculated, and the second correction value is calculated based on the amount of positional deviation. In a case where the first correction value is less than the first set value, the position correction based on the first correction value is not performed in component mounter 16. Therefore, a second correction value is calculated as in the second example without using the first correction value. The second correction value calculated in this manner is transmitted to component mounter 16 via production management computer 42 in a predetermined case. That is, in a case where the second correction value is equal to or greater than the third set value, second communication section 28 transmits the second correction value to component mounter 16. On the other hand, in a case where the second correction value is less than the third set value, second communication section 28 does not transmit the second correction value to component mounter 16. Furthermore, in a case where the second correction value is equal to or greater than the fourth set value, second communication section 28 transmits a stop instruction signal for stopping component mounter 16 to component mounter 16 instead of transmitting the second correction value. In a case where the first correction value and the second correction value are received, control unit 36 of component mounter 16 mounts the component at the correction mounting position calculated using the first correction value and the second correction value. In addition, in a case where only one of the first correction value and the second correction value is received, control unit 36 mounts the component at the correction mounting position calculated using the received correction value (for example, the first correction value or the second correction value). In addition, in a case where neither the first correction value nor the second correction value is received, control unit 36 mounts the component at the mounting position set in advance except when the stop instruction signal is received. The third set value may be set to a value different from the first set value, or may be set to the same value as the first set value. In addition, the fourth set value may be set to a value different from the second set value, or may be set to the same value as the second set value.

Hereinbefore, although Examples 1 to 3 have been described, the specific example is not limited to Examples 1 to 3 described above. In Examples 1 to 3 described above, production management computer 42 includes graph output device 44: however, the configuration is not limited to this. For example, in another example, component mounter 16 may include graph output device 44. In addition, graph 48 output by graph output device 44 is not limited to graphs illustrated in FIGS. 3 and 4. For example, in another example, a bar graph, a pie chart, a polygonal line graph, a band graph, a histogram, a Pareto diagram, or the like may be used. Furthermore, the method of outputting graph 48 by graph output device 44 is not limited to the display on display screen 46 of the display device. For example, in another example, the printing may be performed on a paper surface by a printer device.

In Example 1 described above, print inspection machine 14 includes first correction value calculation section 23 that calculates a first correction value and first communication section 27; however, the configuration is not limited to this. For example, in another example, production management computer 42 may include first correction value calculation section 23 and first communication section 27.

In Example 2 described above, board visual inspection machine 18 includes second correction value calculation section 24 that calculates a second correction value, and second communication section 28; however, the configuration is not limited to this. For example, in another example, production management computer 42 may include second correction value calculation section 24 and second communication section 28.

Hereinbefore, although a specific example of the present disclosure has been described in detail, this is merely illustrative and does not limit the scope of the aspects. The technique described in the aspects includes various modifications and changes to the specific examples illustrated above. The technical elements described in the present description or the drawings exhibit technical usefulness alone or in various combinations and are not limited to the combinations described in the claims as filed. In addition, the techniques illustrated in the present description or the drawings can achieve multiple objects simultaneously and provide technical usefulness by achieving one object in multiple objects.

### REFERENCE SIGNS LIST

10: Component-mounting system 14: Print inspection machine, 16: Component mounter, 18: Board visual inspection machine, 22: Correction value calculation section, 23: First correction value calculation section, 24: Second correction value calculation section, 26: Communication section, 27: First communication section, 28: Second communication section, 32: Board conveyance device, 34: Mounting unit, 36: Control unit, 44: Graph output device, 48: Graph, −SX1, +SX1, −SY1, +SY1: First set value, −SX2, +SX2, −SY2, +SY2: Second set value

1. A component-mounting system comprising:
a print inspection machine configured to inspect a solder pattern printed on a board;
a component mounter configured to mount a component on the board inspected by the print inspection machine; and
a board visual inspection machine configured to inspect the board on which the component is mounted by the component mounter, wherein
the component mounter includes
a mounting unit configured to mount the component on the board, and
a control unit configured to control the mounting unit, and mount the component at a mounting position set in advance without correcting the component using a correction value calculated using at least one of an inspection result of the print inspection machine and an inspection result of the board visual inspection machine in a case where the correction value is less than a first set value, while mounting the component at a correction mounting position obtained by correcting the mounting position using the correction value in a case where the correction value is equal to or greater than the first set value.

2. The component-mounting system according to claim 1, wherein the control unit stops mounting the component on the board in a case where the correction value is equal to or greater than a second set value greater than the first set value.

3. The component-mounting system according to claim 1, wherein
the print inspection machine or the board visual inspection machine includes
a correction value calculation section configured to calculate the correction value using an inspection result, and
a communication section configured not to transmit the correction value calculated by the correction value calculation section to the component mounter in a case where the correction value is less than the first set value, while transmitting the correction value to the component mounter in a case where the calculated correction value is equal to or greater than the first set value.

4. The component-mounting system according to claim 1, wherein
the board includes at least one land and a lead component mounted on the land,
the component-mounting system further comprises
a graph output device configured to output a graph indicating a time-series change in an amount of deviation of the lead component with respect to the land, and
the amount of deviation of the lead component with respect to the land is calculated based on the inspection result of the board visual inspection machine.

5. The component-mounting system according to claim 1, wherein
the print inspection machine includes
a first correction value calculation section configured to calculate a first correction value using an inspection result of the solder pattern printed on the board, and
a first communication section configured not to transmit the first correction value calculated by the first correction value calculation section to the component mounter and the board visual inspection machine in a case where the first correction value is less than a first set value, while transmitting the first correction value to the component mounter and the board visual inspection machine in a case where the calculated first correction value is equal to or greater than the first set value,
the board visual inspection machine includes
a second correction value calculation section configured to calculate a second correction value using a visual inspection result of the component mounted on the board and the first correction value transmitted from the first communication section, and
a second communication section configured not to transmit the second correction value calculated by the second correction value calculation section to the component mounter in a case where the second correction value is less than a third set value, while transmitting the second correction value to the component mounter in a case where the calculated second correction value is equal to or greater than the third set value, and
the control unit of the component mounter mounts the component at the correction mounting position calculated using the first correction value and the second correction value in a case where the first correction value and the second correction value are received.

6. A component mounter comprising:
a mounting unit configured to mount a component on a board;
a board conveyance device configured to carry a board conveyed from a print inspection machine configured to inspect a solder pattern printed on the board into a component mounting position and carry out the board on which the component is mounted at the component mounting position by the mounting unit to a board visual inspection machine; and
a control unit configured to control the mounting unit, and mount the component at a mounting position set in advance without correcting the component using a correction value calculated using at least one of an inspection result of the print inspection machine and an inspection result of the board visual inspection machine in a case where the correction value is less than a first set value, while mounting the component at a correction mounting position obtained by correcting the mounting position using the correction value in a case where the correction value is equal to or greater than the first set value.

7. A component-mounting method comprising:
a print inspection step of inspecting a solder pattern printed on a board;
a component-mounting step of mounting a component on the board inspected in the print inspection step; and
a board visual inspection step of inspecting the board on which the component is mounted in the component-mounting step, wherein
in the component-mounting step,
in a case where a correction value calculated using at least one of an inspection result in the print inspection step and an inspection result in the board visual inspection step is equal to or greater than a first set value, the component is mounted at a correction mounting position obtained by correcting a mounting position set in advance using the correction value, and
in a case where the correction value is less than the first set value, the component is mounted at the mounting position without correcting the component using the correction value.
